(19) United States
(12) Patent Application Publication
(10) Pub. No.: US 2026/0165205 A1
(43) Pub. Date: Jun. 11, 2026

(54) SEMICONDUCTOR PACKAGE

(71) Applicant: Samsung Electronics Co., Ltd., Suwon-si (KR)

(72) Inventor: Sehyeon PARK, Suwon-si (KR)

(21) Appl. No.: 19/290,508

(22) Filed: Aug. 5, 2025

(30) Foreign Application Priority Data
Dec. 9, 2024 (KR) 10-2024-0181944

(51) Int. Cl. H01L 25/07; H01L 23/31

(52) U.S. Cl. CPC H10W 90/00; H10W 74/111; H10W 90/752; H10W 90/754

(57) ABSTRACT

A semiconductor package includes a package substrate, at least one a plurality of semiconductor chips including a first semiconductor chip, the plurality of semiconductor chips comprising a lowermost surface that is spaced apart from an upper surface of the package substrate in a first direction perpendicular to the upper surface of the package substrate, at least one a first chip wire electrically connecting the first semiconductor chip of the plurality of semiconductor chips and to the package substrate, the first chip wire extending in the first direction, and a passive device spaced apart from the upper surface of the package substrate in the first direction and electrically connected to the first semiconductor chip.

### CROSS-REFERENCE TO RELATED APPLICATION

This application claims priority to Korean Patent Applications No. 10-2024-0181944, filed in the Korean Intellectual Property Office on Dec. 9, 2024, the entire contents of which are hereby incorporated by reference.

### BACKGROUND

### Technical Field

The present disclosure relates to a semiconductor package.

### Description of Related Art

Passive devices such as capacitors may be mounted on a semiconductor package. The passive devices can improve the performance of a semiconductor chip that performs functions such as noise filtering, power stabilization, etc.

In general, the passive devices may be mounted on an upper surface or a lower surface of a package substrate. If the passive device is mounted on the upper surface of the package substrate, the manufacturing process can be complicated, and if it is mounted on the lower surface of the package substrate, the area to mount the terminal can be reduced. Accordingly, various methods of mounting the passive devices in the semiconductor package are being studied.

### SUMMARY

In order to address one or more problems (e.g., the problems described above and/or other problems not explicitly described herein), the preset disclosure provides a semiconductor package with improved integration density.

In order to address one or more problems (e.g., the problems described above and/or other problems not explicitly described herein), the present disclosure provides a semiconductor package with improved electrical performance.

According to some example embodiments of the present disclosure, a semiconductor package may include a package substrate, a plurality of semiconductor chips comprising a lowermost surface that is spaced apart from an upper surface of the package substrate in a first direction perpendicular to the upper surface of the package substrate, at least a first chip wire electrically connecting a first semiconductor chip of the plurality of semiconductor chips to the package substrate in the first direction, and a passive device spaced apart from the upper surface of the package substrate in the first direction and electrically connected to the first semiconductor chip.

According to some example embodiments of the present disclosure, a semiconductor package, comprise a printed circuit board including a first chip connection pad, a second chip connection pad, and a device connection pad, a plurality of semiconductor chips including a first semiconductor chip and a second semiconductor chip, a lowermost surface of the plurality of semiconductor chips spaced apart from an upper surface of the printed circuit board in a first direction perpendicular to the upper surface of the printed circuit board, the first semiconductor chip comprising a first chip pad overlapping the first chip connection pad in the first direction, and the second semiconductor chip comprising a second chip pad overlapping the second chip connection pad in the first direction, a capacitor spaced apart from the upper surface of the printed circuit board in the first direction, the capacitor electrically connected to at least one chip of the plurality of semiconductor chips, a first chip wire electrically connecting the first chip pad of the first semiconductor chip to the first chip connection pad, the first chip wire extending in the first direction, a second chip wire electrically connecting the second chip pad of the second semiconductor chip to the second chip connection pad, the second chip wire extending in the first direction, and a device wire electrically connecting the capacitor to the device connection pad, the device wire extending in the first direction.

According to some example embodiments of the present disclosure, a semiconductor package, comprises a printed circuit board including a first chip connection pad and a second chip connection pad, a plurality of semiconductor chips including a first semiconductor chip and a second semiconductor chip, a lowermost surface of the plurality of semiconductor chips spaced apart from an upper surface of the printed circuit board in a first direction perpendicular to the upper surface of the printed circuit board, the first semiconductor chip comprising a first chip pad overlapping the first chip connection pad in the first direction, and the second semiconductor chip at a lower level than the first semiconductor chip and including a second chip pad overlapping the second chip connection pad in the first direction, a first chip wire electrically connecting the first chip pad of the first semiconductor chip to the first chip connection pad, a second chip wire electrically connecting the second chip pad of the second semiconductor chip to the second chip connection pad, and a capacitor disposed on a lower surface of the second semiconductor chip and electrically connected to at least one semiconductor chip of the plurality of semiconductor chips.

According to some examples of the present disclosure, the integration density of the semiconductor package can be improved.

According to some example embodiments of the present disclosure, the electrical performance of the semiconductor package can be improved.

### BRIEF DESCRIPTION OF THE DRAWINGS

The above and other objects, features and advantages of the present disclosure will become more apparent to those of ordinary skill in the art by describing in detail exemplary example embodiments thereof with reference to the accompanying drawings, in which:

FIG. 1 is a cross-sectional view illustrating a semiconductor package according to some example embodiments of the present disclosure;

FIG. 2 is a cross-sectional view illustrating a semiconductor package according to some example embodiments;

FIG. 3 is a cross-sectional view illustrating a semiconductor package according to some example embodiments;

FIG. 4 is a cross-sectional view illustrating a semiconductor package according to some example embodiments;

FIG. 5 is a cross-sectional view illustrating a semiconductor package according to some example embodiments;

FIGS. 6 to 11 are diagrams illustrating intermediate steps of a method for manufacturing a semiconductor package according to some example embodiments;

FIGS. 12 to 15 are diagrams illustrating an intermediate steps of a method for manufacturing a semiconductor package according to some example embodiments;

FIG. 16 is a cross-sectional view illustrating a semiconductor package according to some example embodiments;

FIG. 17 is a cross-sectional view illustrating a semiconductor package according to some example embodiments;

FIG. 18 is a cross-sectional view illustrating a semiconductor package according to some example embodiments; and

FIG. 19 is a cross-sectional view illustrating a semiconductor package according to some example embodiments.

### DETAILED DESCRIPTION

Hereinbelow, a semiconductor package according to some example embodiments of the present disclosure will be described in detail with reference to the drawings.

As used herein, terms representing spatial relationships, such as “bottom,” “below,” “lower,” “top,” and “upper,” are intended only to describe relative positional relationships between elements or patterns shown in the drawings, and are used for ease of understanding only and do not limit the inventive concept at all. The terms for the relative positions in space are intended to encompass changes due to the orientation of a semiconductor device in addition to the directions shown in the drawings. That is, the semiconductor device may be oriented in various directions when used (or manufactured), and the terms for the positions used herein are easily understood by a person skilled in the art.

Throughout the specification, when a component is described as “including” a particular element or group of elements, it is to be understood that the component is formed of only the element or the group of elements, or the element or group of elements may be combined with additional elements to form the component, unless the context clearly and/or explicitly describes the contrary.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

As used herein, components described as being “electrically connected” are configured such that an electrical signal can be transferred from one component to the other (although such electrical signal may be attenuated in strength as it is transferred and may be selectively transferred).

Various pads of a device described herein may be conductive terminals connected to internal wiring of the device, and may transmit signals and/or supply voltages between an internal wiring and/or internal circuit of the device and an external source. For example, chip pads of a semiconductor chip may electrically connect to and transmit supply voltages and/or signals between an integrated circuit of the semiconductor chip and a device to which the semiconductor chip is connected. The various pads may be on or near an external surface of the device and may have a planar surface having dimensions greater than wiring (e.g., X-Y horizontal dimensions of a pad are both greater than the width of an internal writing to which it is connected) to promote an electrical connection to a further terminal, such as a bump or solder ball, and/or an external wiring.

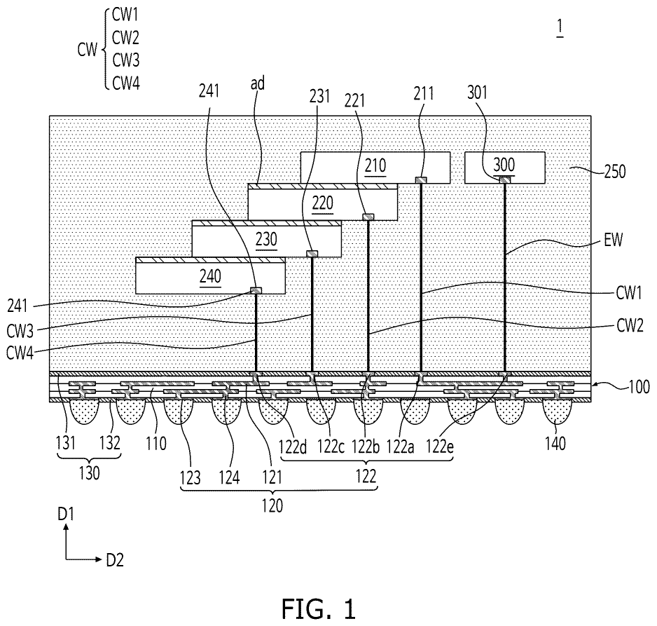

FIG. 1 is a cross-sectional view illustrating a semiconductor package according to some example embodiments.

Referring to FIG. 1, a semiconductor package 1 according to some example embodiments may include a package substrate 100, at least one semiconductor chip 200 (e.g., chips 210, 220, 230, 240), a passive device 300, at least one chip wire CW, a device wire EW, and a mold layer 250. In some example embodiments, the semiconductor package 1 may be an upper package of a package-on-package (POP). In this case, each of the semiconductor package 1, the package substrate 100, the at least one semiconductor chip 200, and the passive device 300 may be referred to as an upper package, an upper package substrate, at least one upper semiconductor chip, and an upper passive device, respectively.

The package substrate 100 may be a printed circuit board (PCB), a ceramic substrate, a wafer for manufacturing a package, an interposer, or a redistribution layer. In some example embodiments, the package substrate 100 may be a multi-layer printed circuit board.

The package substrate 100 may include at least one base insulating layer 110 and a plurality of wiring patterns 120. The base insulating layer 110 may include at least one material selected from phenol resin, epoxy resin, and polyimide. For example, the base insulating layer 110 may include at least one material selected from Flame Retardant 4 (FR-4), tetrafunctional epoxy, polyphenylene ether, epoxy/polyphenylene oxide, bismaleimide triazine (BT), thermount, cyanate ester, polyimide, and liquid crystal polymer.

The plurality of wiring patterns 120 may include internal wiring patterns 121 disposed within the package substrate 100, and the internal wiring patterns 121 may form a wiring layer between the adjacent base insulating layers 110. The internal wiring patterns 121 may form an electrical path, and, in some embodiments, the internal wiring patterns 121 may be planar. The package substrate 100 may include the internal wiring patterns 121 on upper and lower surfaces of the at least one base insulating layer 110. Accordingly, in some embodiments, the package substrate 100 may have two base insulating layers 110, with an internal wiring pattern 121 between the adjacent base insulating layers 110.

The plurality of wiring patterns 120 may include a plurality of upper pads 122 disposed on the upper surface of the at least one base insulating layer 110, a plurality of lower pads 123 disposed on the lower surface of the base insulating layer 110, and a plurality of conductive vias 124. The plurality of conductive vias 124 may extend through the at least one base insulating layer 110 and may electrically connect the wiring patterns 120 disposed on different wiring layers. The upper pads 122, the lower pads 123, and other pads described herein may be conductive terminals connected to internal wiring (e.g., of the package substrate 100, of a semiconductor chip 200, etc.), and may transmit signals and/or supply voltages between an internal wiring and/or internal circuit and an external source.

The plurality of upper pads 122 may include first to fifth upper pads 122a, 122b, 122c, 122d, and 122e for electrically connecting with a plurality of semiconductor chips 200 to be described below. The first to fourth upper pads 122a, 122b, 122c, and 122d may be electrically connected to the first to fourth semiconductor chips 210, 220, 230, and 240, respectively. The fifth upper pad 122e may be electrically connected to the passive device 300. The first to fourth chip pads 211, 221, 231, and 241 may be electrically connected to the first to fourth upper pads 122a, 122b, 122c, and 122d, respectively. In some example embodiments, the first to fourth chip pads 211, 221, 231, and 241 and the first to fourth upper pads 122a, 122b, 122c, and 122d may be aligned along a first direction D1. As illustrated in FIG. 1, each semiconductor chip may comprise at least one connection terminal, for example, a chip pad 211, 221, 231, 241, at a lowermost surface of the semiconductor chip, and each of the connection terminals may be spaced apart from the upper surface of the package substrate 100 with the mold layer 250 in between the connection terminal and the upper surface of the package substrate 100.

The first to fourth upper pads 122a, 122b, 122c, and 122d may be referred to as first to fourth chip connection pads 122a, 122b, 122c, and 122d, respectively, and the fifth upper pad 122e may be referred to as a device connection pad 122e. By being aligned in the first direction D1, a line (or axis) extending vertically (e.g., relative to the orientation illustrated in FIG. 1) along the first direction D1 may pass through one of the chip pads and one of the upper pads. For example, the first chip pad 211 may be aligned along the first direction D1 with the first chip connection pad 122a, the second chip pad 221 may be aligned along the first direction D1 with the second chip connection pad 122b, the third chip pad 231 may be aligned along the first direction D1 with the third chip connection pad 122c, the fourth chip pad 241 may be aligned along the first direction D1 with the fourth chip connection pad 122d, and a device pad 301 of the passive device 300 may be aligned along the first direction D1 with the device connection pad 122e.

An upper end of each conductive via of the plurality of conductive vias 124 may contact at least one of the upper pads 122 or one of the internal wiring patterns 121. A lower end of each conductive via of the plurality of conductive vias 124 may contact at least one of the lower pads 123 or one of the internal wiring patterns 121. The wiring pattern 120 may be formed of copper, nickel, stainless steel, or beryllium copper.

The package substrate 100 may include solder resist layers 130 disposed on upper and lower surfaces. The solder resist layer 130 may include an upper solder resist layer 131 covering the upper surface of at least one base insulating layer 110, with the upper solder resist layer 131 exposing the upper pads 122. The solder resist layer 130 may include a lower solder resist layer 132 covering the lower surface of at least one base insulating layer 110, with the lower solder resist layer 132 exposing the lower pads 123. In some example embodiments, the lower solder resist layer 132 covering the lower surface of at least one base insulating layer 110 may be formed, while the upper solder resist layer 131 covering the upper surface of at least one base insulating layer 110 may not be provided.

In some example embodiments, the solder resist layer 130 may be formed by applying a solder mask insulating ink on the upper and lower surfaces of the base insulating layer 110 with a screen-printing method or an inkjet printing method, followed by curing the same with heat, UV, or IR. Alternatively, the solder resist layer 130 may be formed by applying the photosensitive solder resist over the entire surface with the screen-printing method or the spray coating method or bonding a film-type solder resist material with a laminating method, and removing parts by exposure and development, and curing the same by heat, UV, or IR.

An external connection terminal 140 may be disposed under the package substrate 100. The external connection terminal 140 may be electrically connected to an external device such as a main board. For example, the external connection terminal 140 may include a solder ball, a conductive bump, or a grid array such as a pin grid array, a ball grid array, or a land grid array.

The at least one semiconductor chip 200 may be spaced apart from the upper surface of the package substrate 100 in the first direction D1. The first direction D1 may be defined as a direction perpendicular to the upper surface of the package substrate 100, and a second direction D2 may be defined as a direction parallel to the upper surface of the package substrate 100. The first direction D1 may mean a vertical direction, and the second direction D2 may mean a horizontal direction.

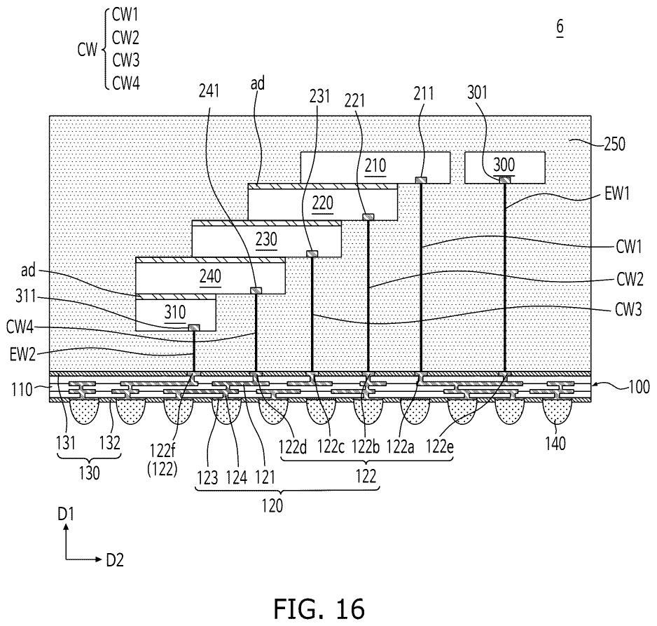

A plurality of semiconductor chips 200 are illustrated in FIGS. 1-19, though, the package substrate 100 may alternatively include a single semiconductor chip. Each of the semiconductor chips 200 may be spaced apart from the upper surface of the package substrate 100 in the first direction D1. The plurality of semiconductor chips 200 may include the first semiconductor chip 210, the second semiconductor chip 220, the third semiconductor chip 230, and the fourth semiconductor chip 240. However, example embodiments are not limited to the above, and other semiconductor chips may be further included. By being spaced apart from the upper surface of the package substrate 100 in the first direction D1, a gap may exist between the plurality of semiconductor chips 200, for example, a lowermost chip of the semiconductor chips 200, and the upper surface of the package substrate 100. In some embodiments, the gap is filled with the mold layer 250. However, as illustrated in FIGS. 16-19, the gap between the lowermost surface of the lowermost chip of the plurality of semiconductor chips 200 and the upper surface of the package substrate 100 may be partially occupied by a second passive device 310 along with the mold layer 250. A lowermost surface of the plurality of semiconductor chips 200 may be the surface that is lowest relative to the first direction D1, and may be the surface of the plurality of semiconductor chips 200 that is in closest proximity to the upper surface of the package substrate 100. In the embodiment of FIG. 1, the lowermost surface of the plurality of semiconductor chips 200 is the lowermost surface of the fourth semiconductor chip 240, while the upper surface of the package substrate 100 is the upper surface of upper solder resist layer 131. As illustrated in FIG. 1, when the semiconductor chips 200 are spaced apart from the upper surface of the package substrate 100 in the first direction D1, a distance separating the lowermost surface of the plurality of semiconductor chips 200 and the upper surface of the package substrate 100 in the first direction D1 may be greater than a thickness (e.g., in the first direction D1) of one of the semiconductor chips 200. In some embodiments, the mold layer 250 and one of the chip wires CW (e.g., chip wire CW4 in FIG. 1) may be the only structures positioned between the lowermost surface of the plurality of semiconductor chips 200 and the upper surface of the package substrate 100 in the first direction D1. As illustrated in FIG. 1, the lowermost semiconductor chip (e.g., fourth semiconductor chip 240 in FIG. 1) does not overlap any semiconductor chips, wherein by not overlapping, any line extending in the vertical first direction D1 from the upper surface of the package substrate 100 to the lowermost semiconductor chip (e.g., fourth semiconductor chip 240 in FIG. 1) will not intersect any semiconductor chips. As illustrated in FIG. 1, when the semiconductor chips 200 are spaced apart from the upper surface of the package substrate 100 in the first direction D1, the distance separating the lowermost surface of the plurality of semiconductor chips 200 and the upper surface of the package substrate 100 in the first direction D1 may be greater than a height (e.g., in the first direction D1) of one of the external connection terminals 140 (e.g., for example when the external connection terminals 140 comprise a solder ball, a conductive bump, etc.).

Each of the plurality of semiconductor chips 200 may be disposed such that an active surface on which a circuit pattern is formed faces the upper surface of the package substrate 100. Each of the plurality of semiconductor chips 200 may include one or more chip pads disposed on the active surface. The first semiconductor chip 210 may include the first chip pad 211 disposed on the active surface of the first semiconductor chip 210, the second semiconductor chip 220 may include the second chip pad 221 disposed on the active surface of the second semiconductor chip 220, the third semiconductor chip 230 may include the third chip pad 231 disposed on the active surface of the third semiconductor chip 230, and the fourth semiconductor chip 240 may include the fourth chip pad 241 disposed on the active surface of the fourth semiconductor chip 240.

The plurality of semiconductor chips 200 may be arranged to form a stack structure. For example, the plurality of semiconductor chips 200 may be offset stacked, such that each of the chip pads 211, 221, 231, 241 may face the package substrate 100 and none of the chip pads 211, 221, 231, 241 are obstructed or blocked. Sidewalls of the plurality of semiconductor chips 200 may not be co-planar with one another, but, rather, the sidewalls may be staggered (e.g., a first sidewall of a first semiconductor chip is not co-planar with an adjacent second sidewall of a second semiconductor chip). An adhesive member ad may be interposed between the first to fourth semiconductor chips 210, 220, 230, and 240.

The second semiconductor chip 220 may be stacked on the lower surface of the first semiconductor chip 210. At least a portion of the second semiconductor chip 220 may be overlapped by at least a portion of the first semiconductor chip 210 in the first direction D1. The second semiconductor chip 220 may be disposed on the lower surface of the first semiconductor chip 210 so as not to be overlapped by the first chip pad 211 of the first semiconductor chip 210 in the first direction D1, such that the second semiconductor chip 220 is offset from the first chip pad 211 in the second direction D2 and does not block or obstruct the first chip pad 211. The third semiconductor chip 230 may be disposed on the lower surface of the second semiconductor chip 220 so as not to be overlapped by the second chip pad 221 of the second semiconductor chip 220 in the first direction D1. As such, the third semiconductor chip 230 is offset from the second chip pad 221 in the second direction D2 and does not block or obstruct the second chip pad 221. The fourth semiconductor chip 240 may be disposed on the lower surface of the third semiconductor chip 230 so as not to be overlapped by the third chip pad 231 in the first direction D1. As such, the fourth semiconductor chip 240 is offset from the third chip pad 231 in the second direction D2 and does not block or obstruct the third chip pad 231.

The second semiconductor chip 220 may be attached to the lower surface of the first semiconductor chip 210 via the adhesive member ad. The adhesive member ad may be disposed between the upper surface of the second semiconductor chip 220 and the lower surface of the first semiconductor chip 210. The third semiconductor chip 230 may be attached to the lower surface of the second semiconductor chip 220 via the adhesive member ad. The adhesive member ad may be disposed between the upper surface of the third semiconductor chip 230 and the lower surface of the second semiconductor chip 220. The fourth semiconductor chip 240 may be attached to the lower surface of the third semiconductor chip 230 via the adhesive member ad. The adhesive member ad may be disposed between the upper surface of the fourth semiconductor chip 240 and the lower surface of the third semiconductor chip 230. For example, the adhesive member ad may be a die attach film (DAF).

The semiconductor chip 200 may be a memory chip. For example, the semiconductor chip 200 may be a dynamic random-access memory (DRAM) chip, a static random-access memory (SRAM) chip, a flash memory chip, an electrically erasable and programmable read-only memory (EPROM) chip, a phase-change random-access memory (PRAM) chip, a magnetic random-access memory (MRAM) chip, or a resistive random-access memory (RRAM) chip. However, example embodiments are not limited to the above, and the semiconductor chip 200 may be a central processing unit (CPU) chip, a graphic processing unit (GPU) chip, or an application processor (AP) chip.

The at least one chip wire CW may electrically connect at least one semiconductor chip 200 to the package substrate 100. The chip wires CW1, CW2, CW3, CW4 may be electrically connected to the chip pads 211, 221, 231, 241 of the semiconductor chips 200 and the chip connection pads 122a, 122b, 122c, and 122d of the package substrate 100, respectively. The plurality of semiconductor chips 200 may be electrically connected to each other through the chip wires CW and the package substrate 100. While FIGS. 1-19 illustrate each wire (e.g., chip wires CW1, CW2, CW3, CW4, bonding wires BW, device wire EW) as a single wire, one or more of the wires may be a part of a set of wires, for example, a plurality of wires. For example, with regard to the first chip wire CW1, while FIGS. 1-19 illustrate only one first chip wire CW1, the first chip wire CW1 may be a part of a set of first chip wires CW1 that electrically connect the first semiconductor chip 210 to the package substrate 100. Likewise, the other examples illustrating one wire (e.g., CW1, CW2, CW3, CW4, BW, EW) may include a plurality of such wires, though only one is shown.

The at least one chip wire CW may extend in the vertical first direction D1. The chip wire CW may be formed by a wire bonding process. The chip wire CW may include nickel (Ni), antimony (Sb), bismuth (Bi), zinc (Zn), indium (In), palladium (Pd), platinum (Pt), aluminum (Al), copper (Cu), molybdenum (Mo), titanium (Ti), gold (Au), silver (Ag), chromium (Sn), tin (Sn), etc.

A plurality of chip wires CW corresponding to the plurality of semiconductor chips 200 may be provided. For example, the plurality of chip wires CW may include first to fourth chip wires CW1, CW2, CW3, and CW4 corresponding to the first to fourth semiconductor chips 210, 220, 230, and 240. Each of the first to fourth chip wires CW1, CW2, CW3, and CW4 may extend in the vertical first direction D1. Therefore, each of the first to fourth semiconductor chips 210, 220, 230, and 240 may be electrically connected to the package substrate 100 through the first to fourth chip wires CW1, CW2, CW3, and CW4. For example, the first chip wire CW1 may extend in the vertical first direction D1 and is electrically connected to the first chip pad 211 and the first chip connection pad 122a, the second chip wire CW2 may extend in the vertical first direction D1 and is electrically connected to the second chip pad 221 and the second chip connection pad 122b, the third chip wire CW3 may extend in the vertical first direction D1 and is electrically connected to the third chip pad 231 and the third chip connection pad 122c, and the fourth chip wire CW4 may extend in the vertical first direction D1 and is electrically connected to the fourth chip pad 241 and the fourth chip connection pad 122d. The first to fourth chip wires CW1, CW2, CW3, and CW4 may be laterally spaced apart from one another in the second direction D2, and may extend parallel to one another along the first direction D1.

The passive device 300 may be spaced apart from the upper surface of the package substrate 100 in the first direction D1. The passive device 300 may be electrically connected to the semiconductor chip 200. The passive device 300 may include a capacitor, for example. For example, the capacitor may include a multilayer ceramic capacitor (MLCC), a low inductance ceramic capacitor (LICC), etc. However, example embodiments are not limited to the above, and the passive device 300 may include an inductor, a resistor, or other device that does not use a separate power input to transfer signals from one end of the passive device 300 to another.

The passive device 300 may be positioned at the same level as the first semiconductor chip 210. The upper surface of the passive device 300 may be positioned at the same level as the upper surface of the first semiconductor chip 210. The upper surface of the passive device 300 and the upper surface of the first semiconductor chip 210 may lie within the same plane and may be coplanar with one another. In some example embodiments, the lower surface of the passive device 300 may be positioned at the same level as the lower surface of the first semiconductor chip 210, such that the lower surfaces of the passive device 300 and the first semiconductor chip 210 may lie within the same plane. A thickness of the passive device 300 and a thickness of the first semiconductor chip 210 may be equal with respect to the first direction D1.

The passive device 300 may provide functions such as decoupling, filtering, resonance attenuation, and/or voltage regulation. The passive device 300 may reduce power noise when the semiconductor package 1 operates at a high frequency. For example, the passive device 300 may be electrically connected to the semiconductor chip 200 and may reduce power noise provided from the package substrate 100 to the semiconductor chip 200. Although FIG. 1 illustrates a single passive device 300, the semiconductor package 1 may comprise a plurality of passive devices 300.

The device wire EW may electrically connect the passive device 300 to the package substrate 100. The device wire EW may connect a device pad 301 of the passive device 300 to the device connection pad 122e of the package substrate 100. The device pad 301 and the device connection pad 122e may be aligned in the first direction D1. For example, the device wire EW may extend in the first direction D1. In some embodiments, the device wire EW may be parallel to the first to fourth chip wires CW1, CW2, CW3, and CW4, with the device wire EW laterally offset from the first to fourth chip wires CW1, CW2, CW3, and CW4 in the second direction D2.

The semiconductor chip 200 and the passive device 300 may be electrically connected to each other. The passive device 300 may be electrically connected to the semiconductor chip 200 through the device wire EW, the package substrate 100, and the chip wire CW. For example, the device pad 301 of the passive device 300 is electrically connected to the device connection pad 300e through the device wire EW.

The mold layer 250 may cover the semiconductor chip 200 and the passive device 300, for example, by surrounding the semiconductor chip 200 and the passive device 300. For example, the mold layer 250 may cover upper surfaces, lower surfaces, and side surfaces of the semiconductor chips 200. In addition, the mold layer 250 may cover the chip wire CW and the device wire EW. The mold layer 250 may be provided on the upper surface of the package substrate 100. The mold layer 250 may include an epoxy molding compound (EMC). In some example embodiments, the mold layer 250 may include a thermosetting resin such as an epoxy resin.

Hereinafter, an aspect different from the semiconductor package 1 described above in FIG. 1 will be described. The same reference numerals are used for the same components described above, and detailed description thereof may be omitted.

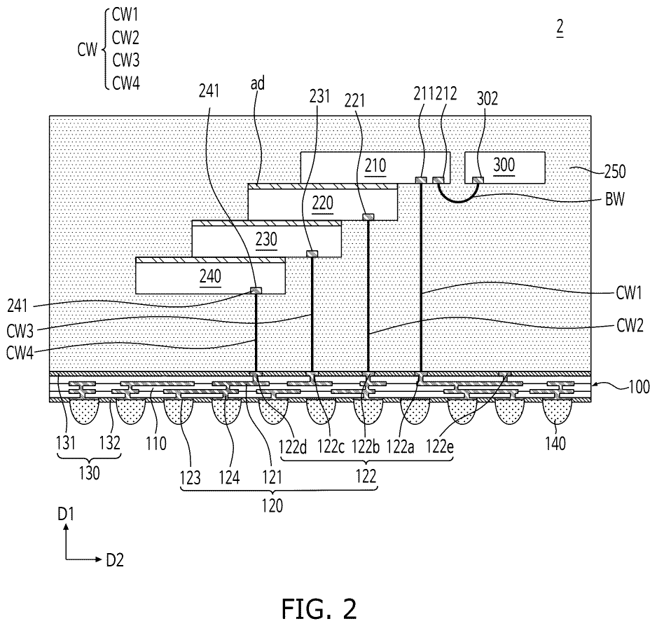

FIG. 2 is a cross-sectional view illustrating a semiconductor package according to some example embodiments.

Referring to FIG. 2, a semiconductor package 2 according to some example embodiments may include the semiconductor chip 200, the passive device 300, and a bonding wire BW.

The semiconductor chips 200 may include chip pads 211, 221, 231, 241 that are electrically connected with the chip wires CW1, CW2, CW3, CW4, respectively, and a connection pad 212 that may be connected to the bonding wire BW. For example, the first semiconductor chip 210 may include the first chip pad 2s11, which is connected with a first chip wire CW1, and a connection pad 212, which is connected with the bonding wire BW. The first chip pad 211 may be formed as a separate configuration from the connection pad 212, but may also be integrally formed. The description of the first semiconductor chip 210 may be equally applicable to the second to fourth semiconductor chips 220, 230, and 240.

The passive device 300 may include a connection pad 302 that is connected to the bonding wire BW. In some example embodiments, the passive device 300 may further include a connection pad (e.g., pad 301 illustrated in FIG. 1) that may be connected with a device wire (e.g., device wire EW illustrated in FIG. 1).

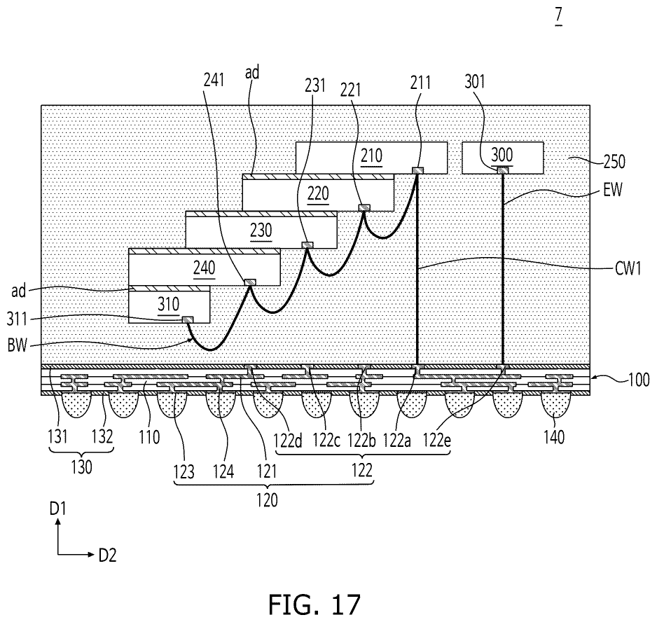

The bonding wire BW may electrically connect the first semiconductor chip 210 and the passive device 300 to each other. The bonding wire BW may connect the connection pad 212 of the first semiconductor chip 210 and the connection pad 302 of the passive device 300 to each other. In some example embodiments, the bonding wire BW is not limited to being connected to the first semiconductor chip 210, and, instead, may be connected to the passive device 300 and one of the other semiconductor chips, for example, the second to fourth semiconductor chips 220, 230, and 240. In some embodiments, the bonding wire BW and the first chip wire CW1 may be connected to different pads (e.g., as illustrated in FIG. 2) or to the same pad (e.g., as illustrated in FIG. 17).

The bonding wire BW may be formed by a wire bonding process. The bonding wire BW may include nickel (Ni), antimony (Sb), bismuth (Bi), zinc (Zn), indium (In), palladium (Pd), platinum (Pt), aluminum (Al), copper (Cu), molybdenum (Mo), titanium (Ti), gold (Au), silver (Ag), chromium (Sn), tin (Sn), etc.

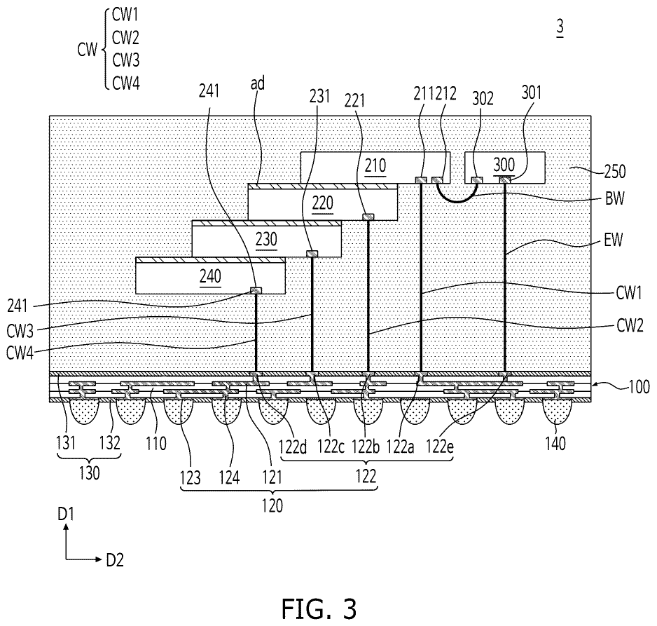

FIG. 3 is a cross-sectional view illustrating a semiconductor package according to some example embodiments.

Referring to FIG. 3, a semiconductor package 3 according to some example embodiments may include the semiconductor chips 200, the passive device 300, the chip wire CW, the device wire EW, and the bonding wire BW.

The semiconductor chips 200 may be electrically connected to the package substrate 100 through the chip wires CW. The passive device 300 may be electrically connected to the package substrate 100 through the device wire EW. The device wire EW may be connected at opposing ends to the device pad 301 of the passive device 300 and the device connection pad 122e of the package substrate 100. The first semiconductor chip 210 and the passive device 300 may be electrically connected to each other through the bonding wire BW. For example, the bonding wire BW may be connected at opposing ends to the connection pad 212 of the first semiconductor chip 210 and the connection pad 302 of the passive device 300. The device pad 301 may be formed as a separate configuration from the connection pad 302, but the device pad 301 and the connection pad 302 may also be integrally formed. In some example embodiments, the bonding wire BW is not limited to being connected to the first semiconductor chip 210, and, instead, may be connected to the passive device 300 and at least one of the other semiconductor chips, for example, the second to fourth semiconductor chips 220, 230, and 240.

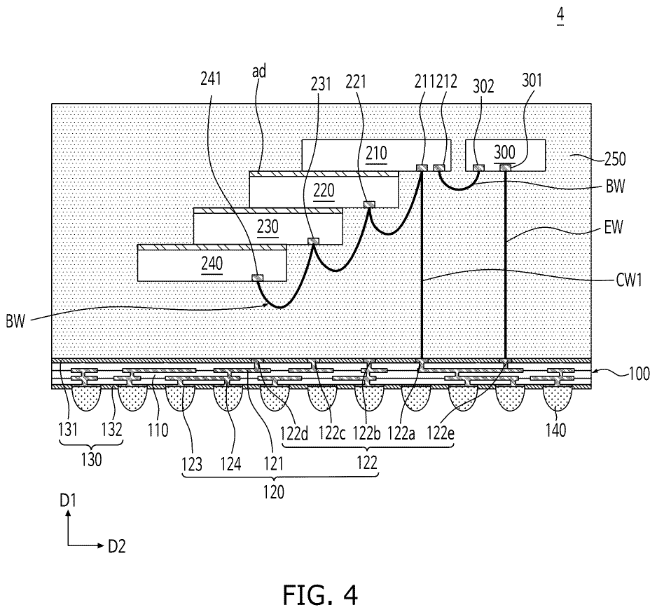

FIG. 4 is a cross-sectional view illustrating a semiconductor package according to some example embodiments.

Referring to FIG. 4, a semiconductor package 4 according to some example embodiments may include the plurality of semiconductor chips 200, the passive device 300, the first chip wire CW1, the device wire EW, and one or more bonding wires BW.

The plurality of semiconductor chips 200 may include the first to fourth semiconductor chips 210, 220, 230, and 240. The first to fourth semiconductor chips 210, 220, 230, and 240 may be offset stacked with each other similar to the configuration illustrated in FIGS. 1-3. Each of the plurality of semiconductor chips 200 may be electrically connected to each other. For example, the first to fourth semiconductor chips 210, 220, 230, and 240 may be electrically connected to each other.

The bonding wires BW may electrically connect each of the plurality of semiconductor chips 200 to each other. The bonding wires BW may be connected to each of the first chip pad 211, the second chip pad 221, the third chip pad 231, and the fourth chip pad 241. In some example embodiments, the chip wire CW1 may be connected to a chip pad other than the first chip pad 211.

The bonding wires BW may be integrally formed, such that a single bonding wire BW is electrically connected to the first chip pad 211, the second chip pad 221, the third chip pad 231, and the fourth chip pad 241. In some example embodiments, the bonding wires BW may include a plurality of separate bonding wires connecting adjacent chip pads to each other. For example, the bonding wires BW may include a first bonding wire connecting the passive device 300 and the first semiconductor chip 210 (e.g., with the first bonding wire electrically connected to the connection pad 302 and the connection pad 212), a second bonding wire connecting the first semiconductor chip 210 and the second semiconductor chip 220 (e.g., with the second bonding wire electrically connected to the first chip pad 211 and the second chip pad 221), a third bonding wire connecting the second semiconductor chip 220 and the third semiconductor chip 230 (e.g., with the third bonding wire electrically connected to the second chip pad 221 and the third chip pad 231), and a fourth bonding wire connecting the third semiconductor chip 230 and the fourth semiconductor chip 240 (e.g., with the fourth bonding wire electrically connected to the third chip pad 231 and the fourth chip pad 241).

The bonding wires BW may be formed by a wire bonding process. The bonding wire BW may include or may be formed of one or more of nickel (Ni), antimony (Sb), bismuth (Bi), zinc (Zn), indium (In), palladium (Pd), platinum (Pt), aluminum (Al), copper (Cu), molybdenum (Mo), titanium (Ti), gold (Au), silver (Ag), chromium (Sn), tin (Sn), etc.

The semiconductor chips 200 and the passive device 300 may be electrically connected to each other through the bonding wires BW. The first semiconductor chip 210 and the passive device 300 may be electrically connected to each other. For example, a bonding wire BW may connect the connection pad 212 of the first semiconductor chip 210 to the connection pad 302 of the passive device 300 to each other. In addition, a separate bonding wire BW may connect one semiconductor chip (e.g., a first semiconductor chip) to another semiconductor chip (e.g., a second semiconductor chip), while another separate bonding wire BW may connect another semiconductor chip (e.g., the second semiconductor chip) to yet another semiconductor chip (e.g., a third semiconductor chip). As such, the present disclosure includes embodiments in which a plurality of bonding wires are provided, and a first bonding wire connects two semiconductor chips, a second bonding wire connects two other semiconductor chips, etc. Alternatively, and as illustrated in FIG. 4, a single bonding wire BW may electrically connect three or more semiconductor chips.

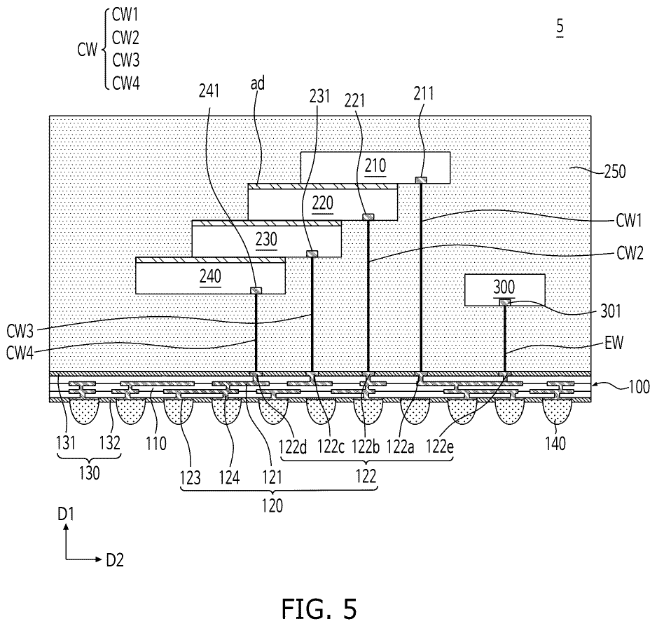

FIG. 5 is a cross-sectional view illustrating a semiconductor package according to some example embodiments.

Referring to FIG. 5, a semiconductor package 5 according to some example embodiments may include the semiconductor chips 200 and the passive device 300. The passive device 300 may be spaced apart from the semiconductor chips 200 in the second direction D2.

In some example embodiments, the passive device 300 may be positioned at a different level than the semiconductor chips 200. For example, the passive device 300 may be positioned at a lower level than at least some chips of the semiconductor chips 200. For example, one or more semiconductor chips of the semiconductor chips 200 are positioned at a level that is higher than a level of the passive device. For example, a distance separating the passive device 300 from the upper surface of the package substrate 100 may be less than a distance separating one or more of the semiconductor chips 200 from the upper surface of the package substrate 100. For example, the distance separating the passive device 300 from the upper surface of the package substrate 100 may be less than the distance separating the first semiconductor chip 210 from the upper surface of the package substrate 100.

The first semiconductor chip 210 may be positioned at the uppermost position among the plurality of semiconductor chips 200, such that a distance separating the first semiconductor chip 210 from the upper surface of the package substrate 100 may be greater than a distance separating any one of the other semiconductor chips (e.g., 220, 230, or 240) from the upper surface of the package substrate 100. As illustrated in FIG. 5, the upper surface of the passive device 300 may be positioned at a lower level than the upper surface of the first semiconductor chip 210. A distance between the passive device 300 and the upper surface of the package substrate 100 may be shorter than a distance between the first semiconductor chip 210 and the upper surface of the package substrate 100.

In some example embodiments, the upper surface of the passive device 300 may be positioned at a level lower than the upper surface of the first semiconductor chip 210, but may be positioned at a level equal to or higher than the upper surface of one of the second semiconductor chip 220, the third semiconductor chip 230, or the fourth semiconductor chip 240. In some example embodiments, a bonding wire BW connecting the passive device 300 and the semiconductor chip 200 may be further included in a similar arrangement as described relative to FIGS. 2-4.

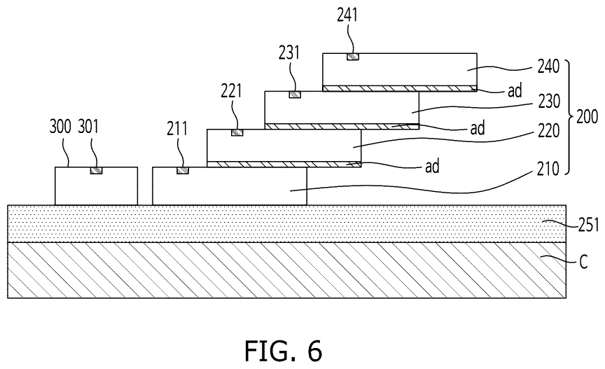

FIGS. 6 to 11 illustrate intermediate steps of a method for manufacturing a semiconductor package according to some example embodiments.

Referring to FIG. 6, a first mold layer 251 may be disposed on a carrier substrate C. The first mold layer 251 may be an epoxy molding compound (EMC) film. In some example embodiments, the first mold layer 251 may include a thermosetting resin such as an epoxy resin.

The first semiconductor chip 210 and the passive device 300 may be disposed on the first mold layer 251. The first semiconductor chip 210 may be disposed such that the first chip pad 211 provided on the active surface faces an opposite direction from the carrier substrate C. The passive device 300 may be disposed such that the device pad 301 faces an opposite direction from the carrier substrate C. The first semiconductor chip 210 and the passive device 300 may be disposed to be spaced apart from each other.

The second semiconductor chip 220 may be stacked on the active surface of the first semiconductor chip 210. The second semiconductor chip 220 may be offset stacked so as not to overlap or cover the first chip pad 211 of the first semiconductor chip 210 in the first direction D1. The second semiconductor chip 220 may be disposed such that the second chip pad 221 provided on the active surface faces an opposite direction from the carrier substrate C. For example, the second semiconductor chip 220 may be attached to the active surface of the first semiconductor chip 210. The adhesive member ad may be interposed between the second semiconductor chip 220 and the first semiconductor chip 210.

The third semiconductor chip 230 may be stacked on the active surface of the second semiconductor chip 220. The third semiconductor chip 230 may be offset stacked so as not to overlap or cover the second chip pad 221 of the second semiconductor chip 220 in the first direction D1. The third semiconductor chip 230 may be disposed such that the third chip pad 231 provided on the active surface faces an opposite direction from the carrier substrate C. For example, the third semiconductor chip 230 may be attached to the active surface of the second semiconductor chip 220. The adhesive member ad may be interposed between the third semiconductor chip 230 and the second semiconductor chip 220.

The fourth semiconductor chip 240 may be stacked on the active surface of the third semiconductor chip 230. The fourth semiconductor chip 240 may be offset stacked so as not to cover, or be overlapped by, the third chip pad 231 of the third semiconductor chip 230 in the first direction D1. The fourth semiconductor chip 240 may be disposed such that the fourth chip pad 241 provided on the active surface faces an opposite direction from the carrier substrate C. For example, the fourth semiconductor chip 240 may be attached to the active surface of the third semiconductor chip 230. The adhesive member ad may be interposed between the fourth semiconductor chip 240 and the third semiconductor chip 230.

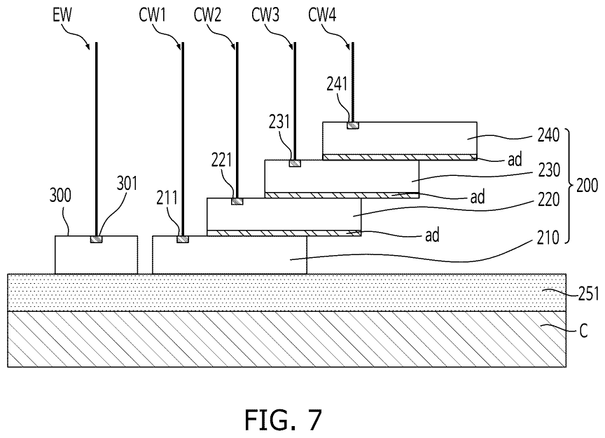

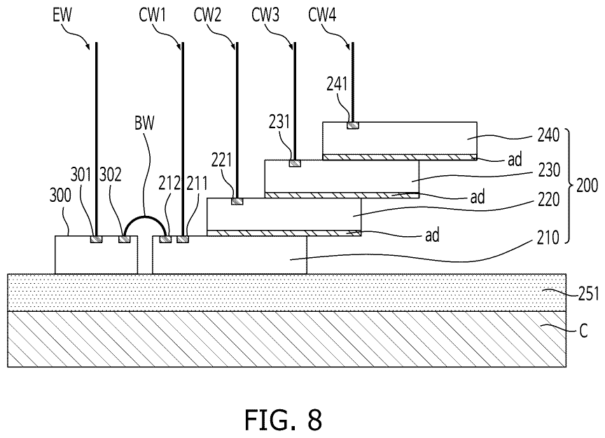

Referring to FIGS. 7 and 8, a wire bonding process may be performed on the plurality of semiconductor chips 200.

The wire bonding process may be performed on each of the semiconductor chips 200. Wires may be formed on the first to fourth semiconductor chips 210, 220, 230, and 240 in the vertical first direction D1. Chip wires CW1, CW2, CW3, CW4 may be formed on the first to fourth chip pads 211, 221, 231, and 241, respectively, in the vertical direction.

The wire bonding process may be performed on the passive device 300. For example, the device wire EW may be formed on the device pad 301 in the vertical direction. In some embodiments, the chip wires CW1, CW2, CW3, CW4 and the device wire EW may extend parallel to one another, and, in some embodiments, may each extend linearly in the first direction D1 from a respective chip pad or device pad. In some embodiments, top ends of the chip wires CW1, CW2, CW3, CW4 and the device wire EW may be at the same level, such that the top ends of the chip wires CW1, CW2, CW3, CW4 and the device wire EW may lie within a plane that is perpendicular to the vertical direction. Accordingly, the chip wires CW1, CW2, CW3, CW4 and the device wire EW may be vertically-extending, straight wires with ends at the same level.

Referring to FIG. 8, the bonding wire BW connecting the first semiconductor chip 210 and the passive device 300 may be further formed. One end of the bonding wire BW may be connected to the connection pad 212 of the first semiconductor chip 210, and an opposing end of the bonding wire BW may be connected to the connection pad 302 of the passive device 300, respectively.

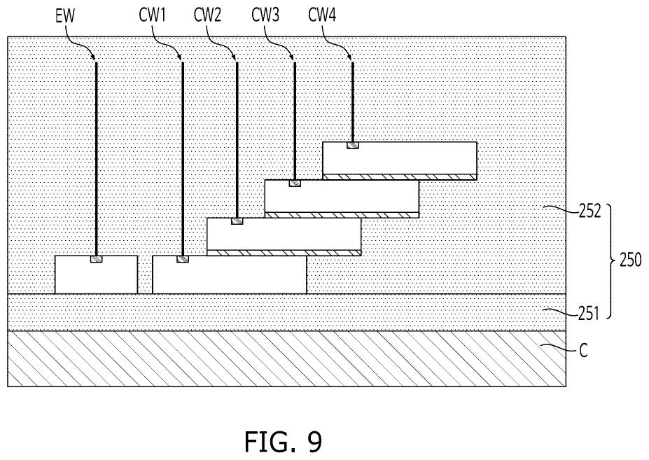

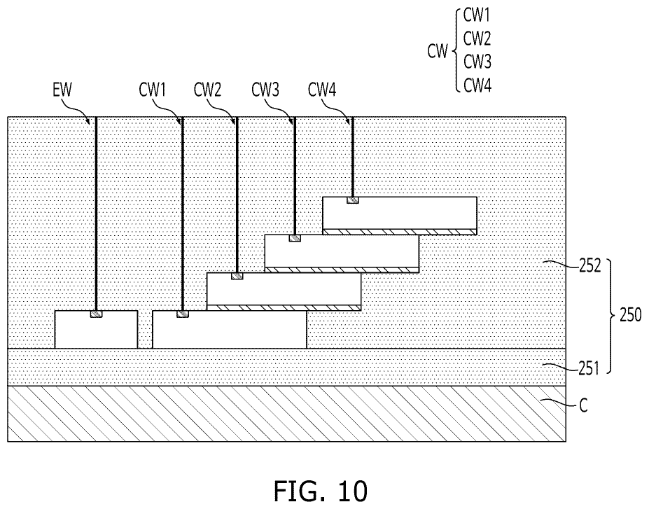

FIGS. 9 and 10 illustrate steps following FIG. 7, in which a second mold layer 252 may be formed on the first mold layer 251. The second mold layer 252 may cover the plurality of semiconductor chips 200 and the passive device 300. The chip wires CW1, CW2, CW3, CW4 and the device wire EW may be surrounded and covered by the second mold layer 252. The first mold layer 251 and the second mold layer 252 may form one mold layer 250.

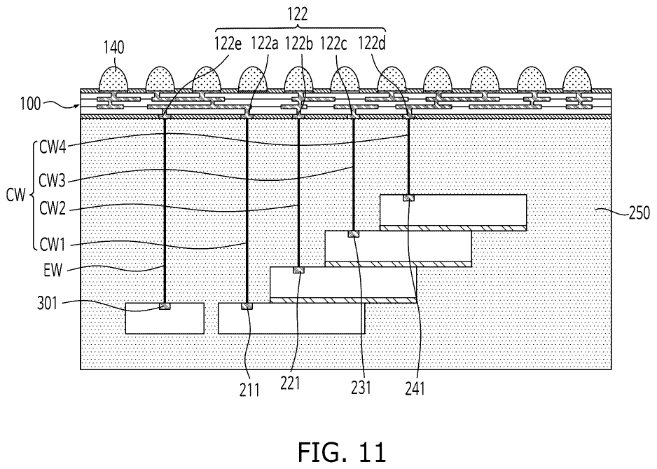

FIG. 9 illustrates the second mold layer 252 covering the ends of the chip wires CW1, CW2, CW3, CW4 and the device wire EW, with a top of the second mold layer 252 being higher than top ends of the chip wires CW1, CW2, CW3, CW4 and the device wire EW. As illustrated in FIG. 10, the chip wires CW1, CW2, CW3, CW4 and the device wire EW may be exposed to the outside to facilitate an electrical connection of the chip wires CW1, CW2, CW3, CW4 and the device wire EW to the package substrate 100, such that the plurality of semiconductor chips 200 and the passive device 300 may be electrically connected to the package substrate 100 (see FIG. 11). For example, as illustrated in FIG. 10, a portion (e.g., a top portion) of the second mold layer 252 may be removed to expose the chip wires CW1, CW2, CW3, CW4 and the device wire EW to the outside of the second mold layer 252. In some embodiments, an amount of the top portion of the second mold layer 252 may be removed to expose at least the ends of the chip wires CW1, CW2, CW3, CW4 and the device wire EW. In some embodiments, the remaining top surface of the second mold layer 252 (e.g., the surface of the second mold layer 252 that is adjacent to the exposed ends of the chip wires CW1, CW2, CW3, CW4 and the device wire EW) may be planar and parallel to the horizontal second direction D2. For example, the top portion of the second mold layer 252 may be removed by a mechanical method using a grinding wheel, etc. However, the grinding method is not limited to the above and may be performed in various ways.

FIG. 11 illustrates the first mold layer 251 and the second mold layer 252 integrated to form the mold layer 250. Referring to FIG. 11, the package substrate 100 may be disposed on the mold layer 250. The package substrate 100 may be disposed such that the upper pads 122 are in contact with the chip wires CW1, CW2, CW3, CW4 and the device wire EW. For example, the upper pads 122 may be disposed to face the chip wires CW1, CW2, CW3, CW4 and the device wire EW.

The first to fourth chip connection pads 122a, 122b, 122c, and 122d may be aligned with the first to fourth chip pads 211, 221, 231, and 241, respectively, along the vertical first direction D1 and aligned in the horizontal second direction D2. For example, by being aligned along the vertical first direction D1 and aligned in the horizontal second direction D2, the first to fourth chip connection pads 122a, 122b, 122c, and 122d may be overlapped by the first to fourth chip pads 211, 221, 231, and 241, respectively, when viewed from above from a plan view. The device connection pad 122e may be aligned with the device pad 301 along the vertical first direction D1 and may be aligned in the horizontal second direction D2. By being aligned along the vertical first direction D1 and aligned in the horizontal second direction D2, the device connection pad 122e may be overlapped by the device pad 301 when viewed from above from a plan view. By being aligned along the vertical first direction D1, the first to fourth chip connection pads 122a, 122b, 122c, and 122d may be in contact with the first to fourth chip wires CW1, CW2, CW3, CW4, respectively, and the device connection pad 122e may be in contact with the device wire EW, such that a gap or space does not exist between the first to fourth chip connection pads 122a, 122b, 122c, and 122d and the first to fourth chip wires CW1, CW2, CW3, CW4, respectively, and a gap or space does not exist between the device connection pad 122e and the device wire EW. By being aligned in the horizonal direction, an axis or line along which each one of the chip wires CW1, CW2, CW3, CW4 and device wire EW extends may intersect a corresponding pad 122a, 122b, 122c, 122d, 122e. As such, the plurality of semiconductor chips 100 and the passive device 300 may be electrically connected to the package substrate 100.

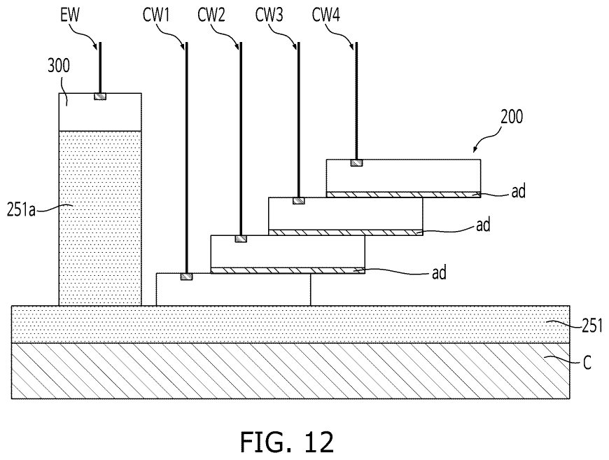

FIGS. 12 to 15 illustrate intermediate steps of a method for manufacturing a semiconductor package according to some example embodiments.

Referring to FIG. 12, the first mold layer 251 may be disposed on the carrier substrate C. At least one semiconductor chip 200 and a mold block 251a may be disposed on the first mold layer 251.

The mold block 251a may have a predetermined thickness that is greater than a thickness of the first mold layer 251. The mold block 251a may be a portion of the first mold layer 251 that is formed thicker than the remaining portion. For example, the mold block 251a may comprise a first thickness measured from the carrier substrate C to the passive device 300, while the first mold layer 251 may comprise a second thickness measured between the carrier substrate C and a top surface of the first mold layer 251, with the first thickness being greater than the second thickness. The thickness of the mold block 251a may be adjusted in consideration of the arrangement of the passive device 300 and is not limited to the thickness illustrated in FIG. 12. The mold block 251a may include an epoxy molding compound (EMC). In some example embodiments, the mold block 251a may include a thermosetting resin such as an epoxy resin.

The passive device 300 may be disposed on the mold block 251a. A distance between the carrier substrate C and the passive device 300 may be greater than a distance between the carrier substrate C and the semiconductor chip 200 connected to the first mold layer 251 (e.g., the first semiconductor chip 210, which is the semiconductor chip closest to the carrier substrate C). With reference to FIG. 12, the passive device 300 may be disposed at a higher level than one or more of the semiconductor chips 200, for example, the first semiconductor chip 210, the second semiconductor chip 220, the third semiconductor chip 230, and the fourth semiconductor chip 240.

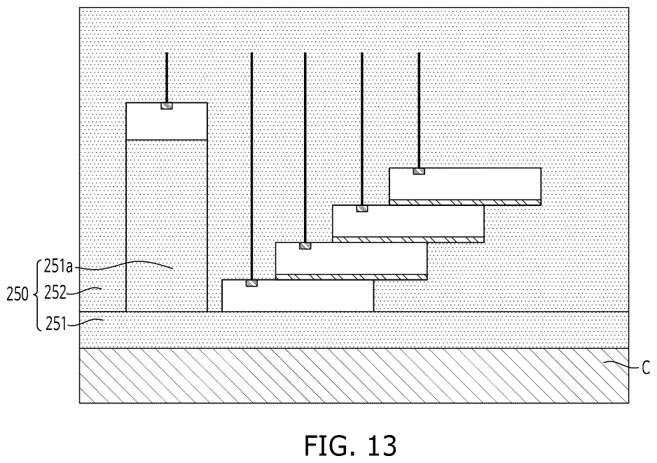

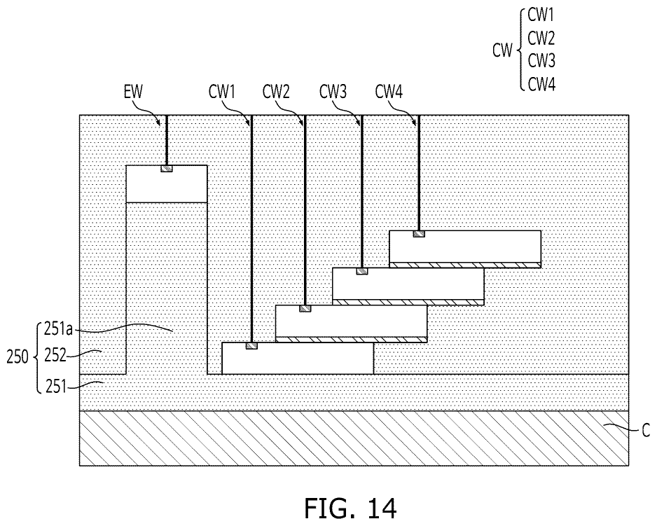

Referring to FIGS. 13 and 14, a wire bonding process may be performed on the plurality of semiconductor chips 200.

The wire bonding process may be performed on each of the semiconductor chips 200. Wires may be formed on the first to fourth semiconductor chips 210, 220, 230, and 240 in the vertical first direction D1. Chip wires CW1, CW2, CW3, CW4 may be formed on the first to fourth chip pads 211, 221, 231, and 241, respectively, in the vertical direction. The wire bonding process may be performed on the passive device 300. For example, the device wire EW may be formed on the device pad 301 in the vertical direction. In some embodiments, the chip wires CW1, CW2, CW3, CW4 and the device wire EW may extend parallel to one another, and, in some embodiments, may each extend linearly from a respective chip pad or device pad. In some embodiments, top ends of the chip wires CW1, CW2, CW3, CW4 and the device wire EW may be at the same level, such that the top ends of the chip wires CW1, CW2, CW3, CW4 and the device wire EW may lie within a plane that is perpendicular to the vertical direction.

FIG. 13 illustrates the second mold layer 252 covering the ends of the chip wires CW1, CW2, CW3, CW4 and the device wire EW, with a top of the second mold layer 252 being higher than top ends of the chip wires CW1, CW2, CW3, CW4 and the device wire EW. The second mold layer 252 may be formed on the first mold layer 251 and the mold block 251a. The second mold layer 252 may cover and surround the plurality of semiconductor chips 200 and the passive device 300. The chip wires CW1, CW2, CW3, CW4 and the device wire EW may be surrounded and covered by the second mold layer 252. The first mold layer 251, the mold block 251a, and the second mold layer 252 may form one mold layer 250.

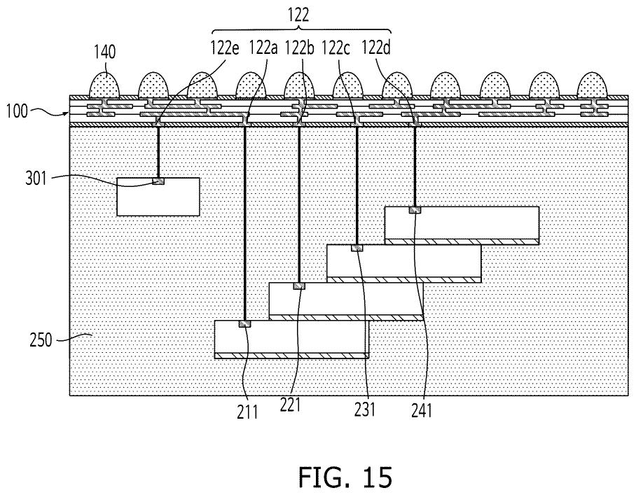

Similar to the description of FIGS. 9-10, as illustrated in FIG. 14, a portion of the second mold layer 252 may be removed to expose the chip wires CW1, CW2, CW3, CW4 and the device wire EW to the outside of the second mold layer 252 to facilitate an electrical connection of the chip wires CW1, CW2, CW3, CW4 and the device wire EW to the package substrate 100. As such, the plurality of semiconductor chips 200 and the passive device 300 may be electrically connected to the package substrate 100 (see FIG. 15). For example, the second mold layer 252 may be removed by a mechanical method using a grinding wheel, etc. However, the grinding method is not limited to the above and may be performed in various ways.

FIG. 15 illustrates the first mold layer 251, the mold block 251a, and the second mold layer 252 integrated to form the mold layer 250.

Referring to FIG. 15, the package substrate 100 may be disposed on the mold layer 250. The package substrate 100 may be disposed such that the upper pads 122 are in contact with the chip wires CW1, CW2, CW3, CW4 and the device wire EW. For example, the upper pads 122 may be disposed to face the chip wires CW1, CW2, CW3, CW4 and the device wire EW.

The first to fourth chip connection pads 122a, 122b, 122c, and 122d may be aligned with the first to fourth chip pads 211, 221, 231, and 241, respectively, along the vertical first direction D1 and may be aligned in the horizontal second direction D2. The device connection pad 122e may be aligned with the device pad 301 along the vertical direction and may be aligned in the horizontal second direction D2. Accordingly, and as illustrated in FIG. 11, the first to fourth chip connection pads 122a, 122b, 122c, and 122d may be in contact with the first to fourth chip wires CW1, CW2, CW3, CW4, respectively, and the device connection pad 122e may be in contact with the device wire EW. As such, the plurality of semiconductor chips 100 and the passive device 300 may be electrically connected to the package substrate 100.

The external connection terminal 140 may be formed on the package substrate 100. The external connection terminal 140 may be formed on a lower surface pad. For example, the external connection terminal 140 may be formed by a solder ball attach (SBA) process. The carrier substrate C (see FIG. 14) may also be removed. After the carrier substrate C is removed, sawing (e.g., dicing, separating, etc.) and inspection processes may be performed.

FIG. 16 is a cross-sectional view illustrating a semiconductor package according to some example embodiments.

Referring to FIG. 16, a semiconductor package 6 according to some example embodiments may include the package substrate 100, the semiconductor chips 200, a first passive device 300, a second passive device 310, the chip wires CW1, CW2, CW3, CW4, a first device wire EW1, and a second device wire EW2.

The package substrate 100 may include the first device connection pad 122e connected to the first passive device 300 (e.g., via the first device wire EW1) and a second device connection pad 122f connected to the second passive device 310 (e.g., via the second device wire EW2). A first device pad 301 of the first passive device 300 may be aligned with the first device connection pad 122e, and a second device pad 311 of the second passive device 310 may be aligned with the second device connection pad 122f along the first vertical direction D1.

The second passive device 310 may be disposed such that the second device pad 311 faces the package substrate 100. The second passive device 310 may be stacked on the lower surface of one of the semiconductor chips 200, for example, on a lowermost surface of a lowermost semiconductor chip. For example, as illustrated in FIG. 16, the lowermost semiconductor chip is the fourth semiconductor chip 240, such that the second passive device 310 may be stacked on the lower surface of the fourth semiconductor chip 240. However, this arrangement is not intended to be limiting, and in other embodiments, the second passive device 310 may be disposed at various positions based on, among other things, the number and arrangement of the semiconductor chips 200. The second passive device 310 may be adhered to the lower surface of the semiconductor chip 200 by the adhesive member ad. In some example embodiments, a portion of the second passive device 310 may be disposed so as not to overlap with the fourth semiconductor chip 240, for example, with the second passive device 310 not covering, obstructing, or overlapped by the fourth chip pad 241.

The second passive device 310 may be laterally offset from the fourth chip pad 241 of the fourth semiconductor chip 240 in the second direction D2, such that a line or axis extending in the vertical first direction D1 may intersect the fourth chip pad 241 but may not intersect the second passive device 310. The fourth chip wire CW4 may be connected to the fourth chip pad 241 of the fourth semiconductor chip 240. The fourth chip wire CW4 may electrically connect the fourth chip connection pad 122d to the fourth chip pad 241.

The second device wire EW2 may extend in the first direction D1, and, in some embodiments, the second device wire EW2 may be parallel to the other wires CW1, CW2, CW3, CW4, EW1. The second device wire EW2 may electrically connect the second passive device 310 to the package substrate 100. The second device wire EW2 may connect the second device pad 311 of the second passive device 310 to the second device connection pad 122f of the package substrate 100.

FIG. 17 is a cross-sectional view illustrating a semiconductor package according to some example embodiments.

Referring to FIG. 17, a semiconductor package 7 according to some example embodiments may include the semiconductor chip 200, the first passive device 300, the second passive device 310, the first chip wire CW1, the device wire EW, and one or more bonding wires BW.

The second passive device 310 may be disposed such that the second device pad 311 faces the package substrate 100. The second passive device 310 may be stacked on the lower surface of the lowermost semiconductor chip 200. For example, the second passive device 310 may be stacked on the lower surface of the fourth semiconductor chip 240. The second passive device 310 may be disposed so as not to overlap with the fourth chip pad 241 of the fourth semiconductor chip 240 in the first direction D1, for example, with the second passive device 310 not covering, obstructing, or overlapped by the fourth chip pad 241. However, the second passive device 310 may be disposed at various positions according to the number and arrangement of the semiconductor chips 200. The second passive device 310 may be adhered to the lower surface of the semiconductor chip 200 by the adhesive member ad. In some example embodiments, a portion of the second passive device 310 may be disposed so as not to be overlapped by the fourth semiconductor chip 240.

The bonding wire BW may be similar or identical to the bonding wire BW of FIG. 4, with the bonding wire BW electrically connecting the second passive device 310 to each of the plurality of semiconductor chips 200. The bonding wire BW may be connected to each of the first chip pad 211, the second chip pad 221, the third chip pad 231, the fourth chip pad 241, and the second device pad 311. In some example embodiments, the chip wire CW1 may be connected to a chip pad other than the first chip pad 211. However, example embodiments are not limited to the above, and some of the plurality of semiconductor chips 200 may be connected to the first passive device 300 by the bonding wire BW.

The bonding wire BW may be integrally formed, such that a single bonding wire BW is connected to all of the chip pads 211, 221, 231, 241, and the second device pad 311. In other embodiments, the bonding wire BW may include a plurality of separate bonding wires BW connecting adjacent chip pads to each other. For example, the bonding wire BW may include a first bonding wire connecting the first semiconductor chip 210 and the second semiconductor chip 220 (e.g., electrically connecting the first and second chip pads 211 and 221), a second bonding wire connecting the second semiconductor chip 220 and the third semiconductor chip 230 (e.g., electrically connecting the second and third chip pads 221 and 231), a third bonding wire connecting the third semiconductor chip 230 and the fourth semiconductor chip 240 (e.g., electrically connecting the third and fourth chip pads 231 and 241), and a fourth bonding wire connecting the fourth semiconductor chip 240 and the second passive device 310 (e.g., electrically connecting the fourth chip pad 241 and the second device pad 311.

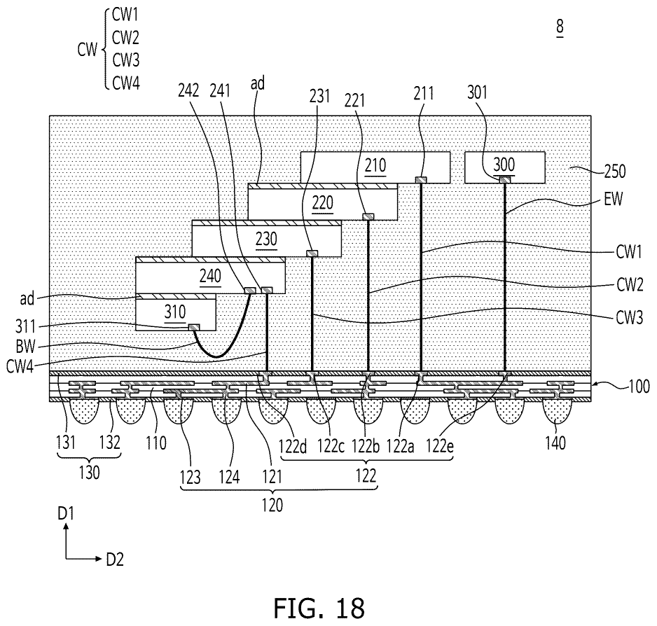

FIG. 18 is a cross-sectional view illustrating a semiconductor package according to some example embodiments.

Referring to FIG. 18, a semiconductor package 8 according to some example embodiments may include the semiconductor chip 200, the first passive device 300, the second passive device 310, the chip wires CW1, CW2, CW3, CW4, the first device wire EW, and the bonding wire BW.

The second passive device 310 may be stacked on the lower surface of one of the semiconductor chips 200. For example, the second passive device 310 may be stacked on the lower surface of the fourth semiconductor chip 240. The second passive device 310 may be disposed so as not to overlap, obstruct, or block the fourth chip pad 241 of the fourth semiconductor chip 240 in the first direction D1. However, in other embodiments, the second passive device 310 may be disposed at various positions according to the number and arrangement of the semiconductor chips 200. The second passive device 310 may be adhered to the lower surface of the semiconductor chip 200 by the adhesive member ad. In some example embodiments, all of the second passive device 310 may be overlapped by the fourth semiconductor chip 240, while in other embodiments, a first portion of the second passive device 310 may be overlapped by the fourth semiconductor chip 240 while a remaining second portion of the second passive device 310 is not overlapped by the fourth semiconductor chip 240. As illustrated in FIG. 18, in some embodiments, the second passive device 310 may comprise a width (e.g., in the second direction D2) that is less than a width of the fourth semiconductor chip 240, such that a footprint of the fourth semiconductor chip 240, when viewed vertically downwardly in a plan view, is greater than a footprint of the second passive device 310.

The second passive device 310 may be disposed such that the second device pad 311 faces the package substrate 100. The second passive device 310 may be disposed so as not to be overlapped by each of the fourth chip pad 241 and a fifth chip pad 242 of the fourth semiconductor chip 240 in the first direction D1. The fourth chip wire CW4 may be connected to the fourth chip pad 241 of the fourth semiconductor chip 240. The fourth chip wire CW4 may electrically connect the fourth chip connection pad 122d to the fourth chip pad 241. The bonding wire BW may be connected to the fifth chip pad 242 of the fourth semiconductor chip 240. The bonding wire BW may electrically connect the fifth chip pad 242 to the second device pad 311.

In some example embodiments, the semiconductor package may further include a bonding wire electrically connecting the plurality of semiconductor chips 200 to each other. Alternatively, the semiconductor package may further include a bonding wire electrically connecting at least one of the plurality of semiconductor chips 200 and the first passive device 300.

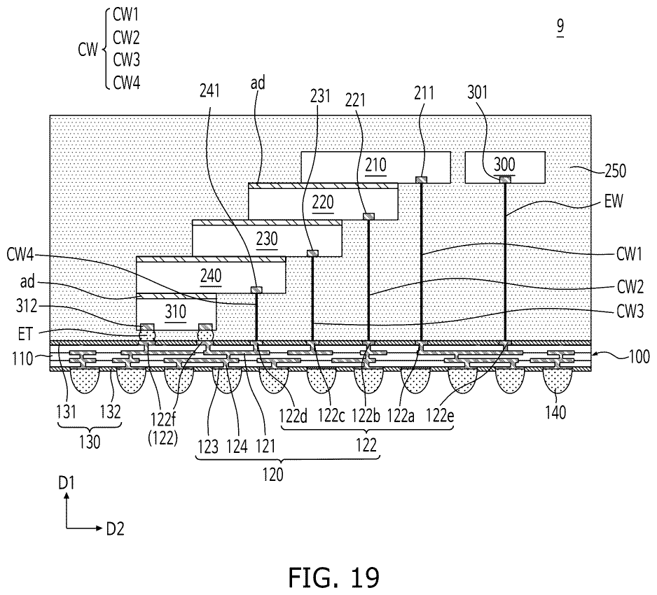

FIG. 19 is a cross-sectional view illustrating a semiconductor package according to some example embodiments.

Referring to FIG. 19, a semiconductor package 9 according to some example embodiments may include the package substrate 100, the semiconductor chips 200, the first passive device 300, the second passive device 310, the chip wires CW, the device wire EW, and a device terminal ET.

The package substrate 100 may include the first device connection pad 122e to be connected to the first passive device 300 and a second device connection pad 122f to be connected to the second passive device 310. The first device pad 301 of the first passive device 300 and the third device pad 312 of the second passive device 310 may be aligned with the first device connection pad 122e and the second device connection pad 122f along the first direction D1, respectively. By being aligned, a first line or a first axis extending in the vertical first direction D1 may intersect the first device pad 301 and the first device connection pad 122e, while a second line or a second axis extending in the vertical first direction D1 may intersect the third device pad 312 and one of the second device connection pads 122f.

The second passive device 310 may be disposed such that the second device pad 311 faces the package substrate 100. The second passive device 310 may be stacked on the lower surface of one of the semiconductor chips 200. For example, the second passive device 310 may be stacked on the lower surface of the fourth semiconductor chip 240. However, this is only an example, and the second passive device 310 may be disposed at various positions according to the number and arrangement of the semiconductor chips 200. The second passive device 310 may be adhered to the lower surface of the semiconductor chip 200 by the adhesive member ad. The second passive device 310 may be positioned relative to the fourth semiconductor chip 240 in a similar manner as described relative to the second passive device 310 in FIGS. 16-18.

The second passive device 310 may be disposed so as not to be overlapped by, or covering, the fourth chip pad 241 of the fourth semiconductor chip 240 in the first direction D1. The fourth chip wire CW4 may be connected to the fourth chip pad 241 of the fourth semiconductor chip 240. The fourth chip wire CW4 may electrically connect the fourth chip connection pad 122d to the fourth chip pad 241. In some example embodiments, each of the plurality of semiconductor chips 200 may be electrically connected to the package substrate 100 by one of the chip wires CW.

A third device pad 312 may be provided in the second passive device 310. The third device pad 312 may be provided on a lower surface of the second passive device 310 facing the package substrate 100. The device terminal ET may be provided on the third device pad 312.

A plurality of device terminals ET may be provided. The device terminal ET may include a conductive material. For example, the device terminal ET may be a solder bump. In some example embodiments, the device terminal ET may take a form of a ball, a pin, or lead. The first passive device 300 may be electrically connected to the package substrate 100 through the device wire EW. The second passive device 310 may be electrically connected to the package substrate 100 through the device terminal ET. A signal transmission distance between the second passive device 310 and the package substrate 100 or the semiconductor chip 200 may be reduced, for example, by reducing the distance between the second passive device 310 and the upper surface of the package substrate 100. In some example embodiments, the first passive device 300 may be positioned closer to the package substrate 100 than as illustrated in FIG. 19. For example, as illustrated in FIGS. 5 and 15, a distance between the upper surface of the package substrate 100 and the first passive device 300 may be less than the distance between the upper surface of the package substrate 100 and the first passive device 300 in FIG. 19, and in some embodiments, the distance between the upper surface of the package substrate 100 and the first passive device 300 may be substantially the same as a distance between the upper surface of the package substrate 100 and the second passive device 310. The semiconductor package 9 according to some example embodiments may include only the second passive device 310, and may not include the first passive device 300.

Although the present disclosure has been described above by way of certain example embodiments and drawings, the present disclosure is not limited thereto, and it goes without saying that various changes and modifications can be made within the equivalent scope of the technical idea of the present disclosure and the claims to be described below by those of ordinary skill in the art.

1. A semiconductor package, comprising:
a package substrate;
a plurality of semiconductor chips including a first semiconductor chip, the plurality of semiconductor chips comprising a lowermost surface that is spaced apart from an upper surface of the package substrate in a first direction perpendicular to the upper surface of the package substrate;
a first chip wire electrically connecting the first semiconductor chip to the package substrate, the first chip wire extending in the first direction; and
a passive device spaced apart from the upper surface of the package substrate in the first direction and electrically connected to the first semiconductor chip.

2. The semiconductor package according to claim 1, further comprising:
a device wire electrically connecting the passive device to the package substrate and extending in the first direction.

3. The semiconductor package according to claim 2, wherein
the first semiconductor chip includes a first chip pad on a lower surface of the first semiconductor chip; and
the plurality of semiconductor chips further comprises a second semiconductor chip including a second chip pad on a lower surface of the second semiconductor chip, the second semiconductor chip stacked on the lower surface of the first semiconductor chip, the second semiconductor chip spaced apart from the first chip pad in a second direction parallel to the upper surface of the package substrate such that the first chip pad does not overlap the second semiconductor chip.

4. The semiconductor package according to claim 3, wherein the first chip wire electrically connects the first chip pad of the first semiconductor chip to the package substrate, and the semiconductor package further comprises:
a second chip wire electrically connects the second chip pad of the second semiconductor chip to the package substrate, the second chip wire extending in the first direction.

5. The semiconductor package according to claim 4, wherein
the package substrate includes a first chip connection pad electrically connected to the first chip wire and a second chip connection pad electrically connected to the second chip wire.

6. The semiconductor package according to claim 3, further comprising a bonding wire electrically connecting the first chip pad of the first semiconductor chip to the second chip pad of the second semiconductor chip.

7. The semiconductor package according to claim 3, wherein an upper surface of the passive device and an upper surface of the first semiconductor chip are at the same level.

8. The semiconductor package according to claim 3, wherein the passive device is at a lower level than the first semiconductor chip.

9. The semiconductor package according to claim 3, wherein
the passive device is spaced apart from the first semiconductor chip in the second direction, and
the semiconductor package further includes a second passive device disposed on a lower surface of the second semiconductor chip.

10. The semiconductor package according to claim 1, further comprising a bonding wire electrically connecting the passive device to the first semiconductor chip.

11. The semiconductor package according to claim 10, further comprising a device wire electrically connecting the passive device to the package substrate, the device wire extending in the first direction.

12. The semiconductor package according to claim 1, further comprising a mold layer provided on the package substrate and covering the first semiconductor chip and the passive device, the mold layer positioned between the lowermost surface of the plurality of semiconductor chips and the upper surface of the package substrate.

13. The semiconductor package according to claim 1, wherein
the package substrate includes a printed circuit board, and
the passive device includes a capacitor.

14. A semiconductor package, comprising:
a printed circuit board including a first chip connection pad, a second chip connection pad, and a device connection pad;
a plurality of semiconductor chips including a first semiconductor chip and a second semiconductor chip, a lowermost surface of the plurality of semiconductor chips spaced apart from an upper surface of the printed circuit board in a first direction perpendicular to the upper surface of the printed circuit board, the first semiconductor chip comprising a first chip pad overlapping the first chip connection pad in the first direction, and the second semiconductor chip comprising a second chip pad overlapping the second chip connection pad in the first direction;
a capacitor spaced apart from the upper surface of the printed circuit board in the first direction, the capacitor electrically connected to at least one chip of the plurality of semiconductor chips;
a first chip wire electrically connecting the first chip pad of the first semiconductor chip to the first chip connection pad, the first chip wire extending in the first direction;
a second chip wire electrically connecting the second chip pad of the second semiconductor chip to the second chip connection pad, the second chip wire extending in the first direction; and
a device wire electrically connecting the capacitor to the device connection pad, the device wire extending in the first direction.

15. The semiconductor package according to claim 14, comprising a bonding wire electrically connecting the capacitor to the first semiconductor chip.

16. The semiconductor package according to claim 14, wherein an upper surface of the capacitor is at a lower level than an upper surface of the first semiconductor chip.

17. The semiconductor package according to claim 14, further comprising a bonding wire electrically connecting the first chip pad to the second chip pad.

18. The semiconductor package according to claim 14, wherein
the printed circuit board further includes a second device connection pad, and
the semiconductor package includes:
a second capacitor disposed on a lower surface of the second semiconductor chip; and
a device terminal electrically connecting the second capacitor to the second device connection pad.

19. A semiconductor package, comprising:
a printed circuit board including a first chip connection pad and a second chip connection pad;
a plurality of semiconductor chips including a first semiconductor chip and a second semiconductor chip, a lowermost surface of the plurality of semiconductor chips spaced apart from an upper surface of the printed circuit board in a first direction perpendicular to the upper surface of the printed circuit board, the first semiconductor chip comprising a first chip pad overlapping the first chip connection pad in the first direction, and the second semiconductor chip at a lower level than the first semiconductor chip and including a second chip pad overlapping the second chip connection pad in the first direction;
a first chip wire electrically connecting the first chip pad of the first semiconductor chip to the first chip connection pad;
a second chip wire electrically connecting the second chip pad of the second semiconductor chip to the second chip connection pad; and
a capacitor disposed on a lower surface of the second semiconductor chip and electrically connected to at least one semiconductor chip of the plurality of semiconductor chips.

20. The semiconductor package according to claim 19, further comprising at least one of a device wire electrically connecting the capacitor to the printed circuit board and a bonding wire electrically connecting the capacitor to at least one semiconductor chip of the plurality of semiconductor chips.
